(19) United States
(12) Patent Application Publication
(10) Pub. No.: US 2004/0137706 A1
(43) Pub. Date: Jul. 15, 2004

(54) Method of manufacturing semiconductor device

(76) Inventor: Koichi Kaneko, Miyagi (JP)

Correspondence Address: RABIN & Berdo, PC, 1101 14TH STREET, NW, SUITE 500, WASHINGTON, DC, 20005, US

(21) Appl. No.: 10/712,323

(22) Filed: Nov. 14, 2003

(30) Foreign Application Priority Data
Jan. 10, 2003 (JP) 005024/2003

(51) Int. Cl. H01L 21/441

(52) U.S. Cl. 438/597; 438/659; 438/664; 438/658

(57) ABSTRACT

A cobalt layer is formed over an entire surface including over a device isolation region. Silicon ions are selectively implanted into only the cobalt layer on the device isolation region and thereafter a silicidation reaction is done, whereby local interconnects are formed between source and drain regions of adjacent MOS transistors.

### BACKGROUND OF THE INVENTION

1. Field of the Invention

The present invention relates to an interconnect for connecting between adjacent transistors of a semiconductor device, and particularly to a method of connecting between diffusion layers of MOS transistors by a silicide interconnect.

2. Description of the Related Art

In order to micro-fabricate a semiconductor integrated circuit, there is a need to form an interconnect without defining a contact hole to connect between adjacent MOS transistors. To this end, a local interconnect technology (see Japanese Patent Application Laid-Open No. Hei 8(1996)-301612 and Japanese Patent Application Nos. 2000-114262 and 2002-26141) has been used which forms an interconnect on a self-alignment basis without forming a contact hole.

However, the conventional local interconnect technology for connecting between the adjacent MOS transistors by means of silicide needs to supply silicon by some kind of method for the purpose of silicidation. In particular, a problem arises in that there is a need to form a silicon supply source on a device isolation region formed of an oxide film or the like, which is free of the silicon supply source (see Japanese Patent Application No. 2000-114262), and an interconnect must be formed in a necessary place alone, thus complicating a manufacturing process.

### SUMMARY OF THE INVENTION

The present invention provides a method of manufacturing an interconnect for connecting via a device isolation region between source-drain diffusion regions of adjacent MOS transistors formed with being spaced the device isolation region from each other, which comprises the steps of forming a high melting-point metal layer over an entire surface including the adjacent MOS transistors, selectively introducing a silicon element into the high melting-point metal layer on the device isolation region, thereafter performing thermal treatment for silicidation to thereby cause a silicon substrate and a high melting-point metal to react at diffusion layers and allow the introduced silicon and the high melting-point metal to react at the device isolation region, and selectively removing the unreacted high melting-point metal layer thereby to form a connecting interconnect.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 is a process cross-sectional view showing a method of manufacturing a semiconductor device, for describing an embodiment of the present invention;

FIG. 2 is a process cross-sectional view illustrating the method of manufacturing the semiconductor device in succession to FIG. 1, for describing the embodiment of the present invention; and

FIG. 3 is a process cross-sectional view depicting the method of manufacturing the semiconductor device in succession to FIG. 2, for describing the embodiment of the present invention.

### DETAILED DESCRIPTION OF THE INVENTION

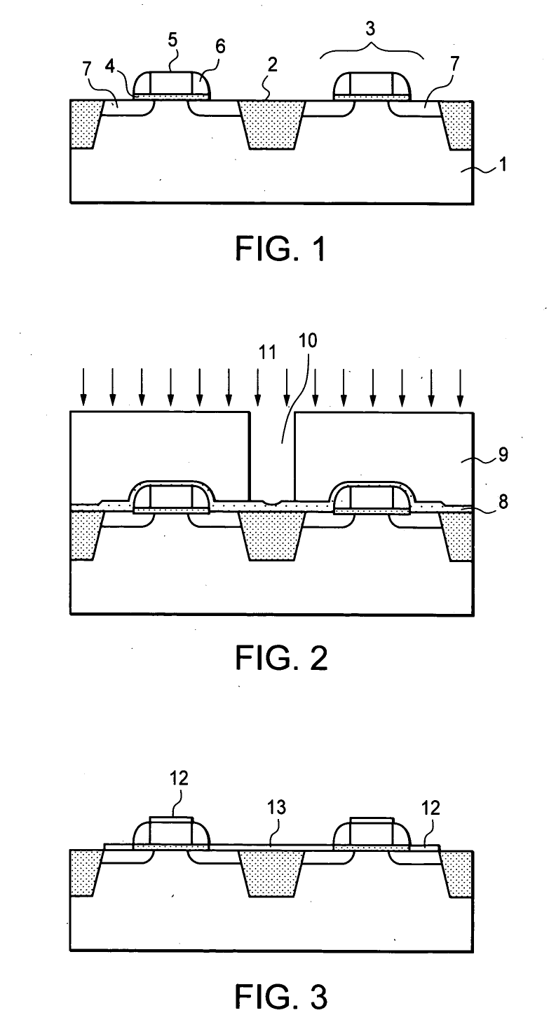

Process diagrams for describing a first embodiment of the present invention are shown in FIGS. 1 through 3. Device isolation regions 2 and active regions 3 are first formed in a silicon substrate 1. Further, each of source-drain regions 7 is formed on a self-alignment basis by a gate insulating film 4, a gate electrode 5 made up of polycrystal silicon, side walls 6 and an ion implantation technology (see FIG. 1).

Next, a cobalt (Co) layer 8 is deposited over the entire surface. After the formation of a resist 9 over the whole surface, only part of the device isolation region 2 is opened by photolithography technology to define a contact hole 10. Implantation 11 of silicon (Si) ions into the contact hole 10 is performed by ion implantation technology (see FIG. 2).

Subsequently, a lamp anneal process is performed at about 500° C. to 600° C. to silicidize the cobalt layer 8 by salicide technology. Since the silicon is supplied only to the gate electrodes 5 each formed of the polycrystal silicon, the source-drain regions 7 of the silicon substrate, and the opening 10 implanted with the silicon ions, silicide layers 12 and local interconnects 13 are formed at their parts alone. Since no silicide layers are formed because no silicon is supplied to other parts, they are selectively removed by etching through the use of an ammonia-hydrogen peroxide solution or the like (see FIG. 3).

Next, a high-temperature lamp anneal process is done at about 800° C. to 900° C. to accelerate a silicide reaction between the silicon and cobalt, thereby reducing the resistances of the cobalt silicide interconnects 12 and local interconnect 13. Consequently, the local interconnects 13 for adjacent MOS transistors are formed on a self-alignment basis.

According to the embodiment of the present invention as described above, since the silicon ions are implanted into the cobalt layer 8 on the device isolation regions 2 by the ion implantation method to thereby carry out the silicidation reaction, the process becomes simple. Further, since only the necessary silicon ions can be injected therein, the optimum local interconnects in which no excessive silicon exists, can be formed.

While the present invention has been described with reference to the illustrative embodiment, this description is not intended to be construed in a limiting sense. Various modifications of the illustrative embodiment, as well as other embodiments of the invention, will be apparent to those skilled in the art on reference to this description. It is therefore contemplated that the appended claims will cover any such modifications or embodiments as fall within the true scope of the invention.

What is claimed is:

1. A method of manufacturing a semiconductor device having interconnects connected with a first diffusion region and a second diffusion region formed in a silicon substrate with being spaced a device isolation region from each other, comprising the steps of:
forming a high melting-point metal layer over an entire surface including over the device isolation region and the first and second diffusion layers;
selectively introducing a silicon element into the high melting-point metal layer on the device isolation region;
silicidizing by thermal treatment the high melting-point metal layer having introduced therein the silicon element on the first and second diffusion layers and the device isolation region; and
selectively removing the high melting-point metal layer to be silicidized remaining unreacted.

2. The method according to claim 1, wherein the high melting-point metal layer is a cobalt layer.

3. The method according to claim 1, wherein said introduction is done by an ion implantation method.

4. A method of manufacturing a semiconductor device having interconnects for connecting a first diffusion region of a first MOS transistor and a second diffusion region of a second MOS transistor both formed in a silicon substrate with being spaced a device isolation region from each other, comprising the steps of:
forming a high melting-point metal layer on an entire surface including the first and second MOS transistors;
selectively introducing a silicon element into the high melting-point metal-layer on the device isolation layer;
silicidizing by thermal treatment the high melting-point metal layer having introduced therein the silicon element on the first and second diffusion layers and the device isolation region; and
selectively removing the high melting-point metal layer to be silicidized remaining unreacted.

5. The method according to claim 4, wherein the high melting-point metal layer is a cobalt layer.

6. The method according to claim 4, wherein said introduction is done by an ion implantation method.
